(19) United States
(12) Patent Application Publication
(10) Pub. No.: US 2016/0258053 A1
(43) Pub. Date: Sep. 8, 2016

(54) Machine and Process for building 3-Dimensional Metal and Composite Structures by Using Carbonyl and Other Gases

(71) Applicant: Joseph Robert Pickens, Glenelg, MD (US)

(72) Inventor: Joseph Robert Pickens, Glenelg, MD (US)

(73) Assignee: Joseph Robert Pickens, Glenelg, MD (US)

(21) Appl. No.: 14/636,326

(22) Filed: Mar. 3, 2015

(51) Int. Cl. C23C 16/16; C23C 16/455; C23C 16/50; C23C 16/46

(52) U.S. Cl. CPC C23C 16/16; C23C 16/46; C23C 16/4557; C23C 16/50

(57) ABSTRACT

The current invention teaches a process to add transition metals to a substrate with careful, spacial control to build up regions selectively, and a machine to enable this process to be performed. The process is amenable to doping with other gases to provide dispersion strengthening and/or to form metal matrix composites. In addition, the process is capable of forming laminar or topologically layered materials. In the present invention, a heated nozzle with a variable orifice projects carbonyl gas or gases at the appropriate temperature to precise locations on a surface. The coordinates on the substrate over which the nozzle is located can be computer controlled. Furthermore, the orifice of the nozzle and the flow rate are controlled to widen or narrow the area of deposition. The substrate can be heated to a temperature where transition metal carbonyl deposition is optimal or near optimal, or heated below the optimal region such that the heated carbonyl gas from the nozzle leads to rapid deposition in the desired localized region. The structure can be built up into complex shapes as desired.

### BACKGROUND OF THE INVENTION

The carbonyl or Mond process was discovered in 1884 when Ludwig Mond noticed that hot carbon monoxide gas would severely corrode nickel. After extensive research, the process was found to exploit the ability of carbon monoxide to form compounds with 18 transition elements from the vanadium group to the nickel group of the periodic table. It is recognized that technetium has no stable isotopes. These transition elements undergo carbonyl or carbonyl+additional gas reactions. The process works particularly well for nickel, iron and cobalt and is most mature in these alloy systems. Importantly, the carbonyl process is reversible. That is, any of the 18 transition metals can be pulled off a substrate, or deposited onto a substrate, depending upon temperature and pressure of the carbonyl gas or gas mixture. Some of the carbonyl gases that can be used include Ni(CO)₄, Fe(CO)₅, Co2(CO)₈, Cr(CO)₆, W(CO)₆, Mo(CO)₆, Re₂(CO)₂₀and RuCO₅.

The nickel carbonyl process is at a high technology readiness level so will be discussed as an example. Hundreds of millions of pounds of nickel are won from ores each year by the carbonyl process in Canada, Europe and China. In general, at about 80° C. and ambient pressure, nickel reacts with carbon monoxide to form nickel carbonyl:

Ni+4CO→Ni(CO)₄

At about 150-175° C., the reaction is reversed with nickel being chemically reduced and the nickel will deposit on virtually any substrate that is in this temperature range. In part because of the low temperatures involved, carbonyl processing can win nickel from low grade sources, and deposit nickel onto substrates such that nickel costs at about 80% of the prevailing nickel price on the London Metal Exchange. The behavior of carbonyl cobalt and iron is similar. Various transition elements can be co-deposited or sequentially deposited providing the scientist-surface engineer with numerous alloy options to reduce corrosion and wear and control electromagnetic performance and signature.

The carbonyl gases can be doped with B₂H₆ or SiH₄to add boron or silicon, respectively. Methane (CH₄) doping can add carbon and ammonia (NH₃) doping can add nitrogen. Campbell et. al.¹ showed that doping with about 4 at % B increases the hardness of nickel fivefold. This is just one example of how gaseous processing can be used to produce hard, wear-resistant surfaces. Reducing wear has wide ranging benefits for industries including automotive, mining, machine tool and others. ¹ A. N. Campbell, A. W. Mullendore, C. R. Hills, J. B. Vandersande, J. Mat Sci. 23, (1988), 4049-58

The carbonyl process is non-line-of-sight such that at the proper temperature and pressure range any surface will be a site for transition metal deposition. For example at 150-175° C., metal, ceramic and stable polymer surfaces will become coated with nickel in the presence of nickel carbonyl gas. This includes irregular surfaces and orifices such as drilled holes in the substrate. The deposition rate is mainly a function of temperature and pressure.

Engineers at CVMR in Canada fabricated a mandrill for a tube, heated it to 175° C. in the presence of carbonyl nickel gas, and fabricated over 600 near-net shape tubes for the Sudbury Neutrino Observatory [http://www.cvmr.ca/refining.php]. In addition, the engineers fabricated over 1200 near net shape nickel end caps. This clearly shows that the carbonyl process can be used to perform what is now called additive manufacturing to net or near net shape over suitable substrate geometry. In the present invention, a radically new approach was conceived for additive manufacturing and/or surface engineering using carbonyl gases and a machine was designed to produce such additive manufactured or surface engineered structures from up to eighteen transition elements.

### SUMMARY OF THE INVENTION

The current invention teaches a process to add transition metals to a substrate with careful, spacial control to build up regions selectively, and a machine to effect this process. The process is amenable to doping with other gases to provide dispersion strengthening and/or to form metal matrix composites. In addition, the process is capable of forming laminar or topologically layered materials. In the present invention, a heated nozzle with a variable orifice projects carbonyl gas or gases at the appropriate temperature to precise locations on a surface. The coordinates on the substrate over which the nozzle is located can be computer controlled. Furthermore, the orifice of the nozzle and the flow rate are controlled to widen or narrow the area of deposition. The substrate can be heated to a temperature where transition metal carbonyl deposition is optimal or near optimal, or heated below the optimal region such that the heated carbonyl gas from the nozzle leads to rapid deposition in the desired localized region. The structure can be built up into complex shapes as desired. The depositions are made at temperatures far below the melting point of the transition metal leading to refined microstructures and superior properties.

Note that researchers have used external heat sources to keep the substrate at the optimal deposition temperature to account for cooling resulting from the endothermic carbonyl deposition reaction (U.S. Pat. No. 4,957,543) to make nickel foams. In the present invention, external heat sources can be used including infrared heat lamps, LASERs, eddy current sources and others to supplement the heat provided by the hot carbonyl gas from the nozzle. LASERS are particular advantageous because they can provide local heating with a high degree of special precision.

Although there is prior art on the carbonyl process, a literature and patent survey revealed that no inventor has used a nozzle of the present invention to deposit transition metals from the gaseous state to localized regions under computer control. Moreover, no prior art teaches control of gaseous deposited metal thickness with spacial control as in the present invention. Furthermore, the teachings of the present invention enable control of thickness and composition in different spacial regions of the deposit, which is not claimed in prior art.

### PRIOR ART

Milinkovic, Reynolds and Terekhov [2] in U.S. Pat. 6,132,518 claim an apparatus and process for depositing and reclaiming nickel from the vapor phase. Their patent claims a superior method of reclaiming nickel carbonyl by using a tertiary condensation unit. Although they do claim improved deposition of nickel from the vapor phase, they do not contemplate the precise spatial control taught the present method and apparatus for gaseous deposition. Furthermore, they do not claim near net shape parts fabrication of nickel or near net fabrication of other transition elements.

Jenkin [3-6] was a prolific inventor in the field of gaseous deposition. In U.S. Pat. No. 3,158,499 Jenkin teaches a method of depositing metals into blind holes by using a pulsating gas. In U.S. Pat. No. 3,160,517, Jenkin teaches a method to deposit metals through the pores of a porous body. In U.S. Pat. No. 3,167,831, Jenkin teaches a method for making molds by gaseous deposition where liquid sodium is used to prevent distortion of the mold. In U.S. Pat. No. 4,606,941, Jenkin teaches a method for coating small objects with a metal where the objects are placed in a heated trough prior to coating by gaseous deposition. The trough is used to surround the object with a heat sink to counter the cooling caused by the endothermic metal deposition. The present invention differs from those of Jenkin in significant ways that are not obvious to one skilled in the art. The present invention supplies the carbonyl or other metal—containing gas by a heated nozzle so the limiting effects of endothermic cooling are circumvented. In addition, the present invention does not require embedding the objects to be coated into a heat sink as external heat sources are used to further alleviate the limiting effects of endothermic cooling. The present invention enables molds to be made with variable wall thickness to account for distortion stresses without relying on a liquid metal, and its attendant practical problems including but not limited to liquid metal embrittlement, to support the mold. The innovative nozzle of the present invention enables the user to selectively deposit metals to varying thickness on solid objects or different regions of a porous body. Finally, the present invention teaches methods of layering and/or mixing different transition metals or varying thicknesses over virtually any substrate. This was not contemplated by Jenkin.

Babjak, Ettel and Paserin [7] (U.S. Pat. No. 4, 957,543) teach a method for making high conductivity nickel foam for battery applications. They deposit nickel from the vapor state over a thermally decomposable porous material. To compensate for the heat loss during the endothermic decomposition of nickel carbonyl gas, they used an infra-red heat source external to the coating chamber that passes through a Teflon polymer, Pyrex glass, or quartz window. in the present invention, infra-red heat sources are considered but also external laser heat sources which provide far greater spacial precision. Babjak et. al. teach a process for making bulk nickel foam and not a wide variety of objects where local control of thickness is attained while enabling bulk deposition where desired. Furthermore, Babjak et. al. do not teach adding heat through a precision nozzle that carries the carbonyl gas.

Milinkovic, Mathews and Davy [8] in U.S. Pat. No. 5,470,651 teach mandrels made from ceramic or organic composites for the manufacture of nickel shells by the carbonyl process. The materials for the mandrills are designed to have the same coefficient of thermal expansion as nickel and the targeted application are nickel molds for the manufacture of plastic articles. They claim a range of CTEs between 10 and 16×10⁻⁶ mm/mm/° C. and list numerous materials to be added to the matrix mandrel material. However, they do not teach direct deposition of transition metals by the carbonyl process from the gaseous state through a nozzle with spacial resolution. Their teachings are for the molds used to make rather large depositions of nickel for molds.

### BRIEF DESCRIPTION OF THE DRAWINGS

FIG. 1 is one embodiment of a machine, including chamber of the present invention.

1 Heat source, e.g. laser to provide a focused heat source in the range 170-180° C.
2 Carbonyl delivery nozzle to be kept in the range of 60-70° C. via pipe tracing. Temperature not to exceed 90° C.
3 Diameter of laser focus can be adjustable depending on size of part required
4 Base plate temperature to be in the range 60-70° C.
5 Insulated chamber to be heated to the range 60-70° C.
6 Carbonyl source; gas to be about 90% carbonyl in strength
7 Carbonyl recovery system reclaims gases to be re-used.
8 Three axis articulated head (control axis arms not shown for diagram clarity)
9 Carbonyl gas that is not decomposed will fill chamber and needs to be reclaimed
10 Flexible feed line

FIG. 2 is a cross section of one embodiment of a nozzle of the present invention

11 Precision main carbonyl gas feed tube. Tubes of smaller inner diameters could be inserted for fine detail control on the workpiece
12 Orifices for high deposition rate carbonyl feed
13 Negative pressure orifices to remove carbon monoxide and excess carbonyl and other gases
14 Heat source
15 Concentric ring of valves to control the volume to the orifices (12)
16 Gas recovery tube

### 17 Carbonyl gas in

### 18 Coolant out

### 19 Coolant in

20 Baseplate on which to build transition metal deposit

FIG. 3 is an alternative embodiment for a nozzle of the present invention designed to minimize the amount of carbonyl in the chamber. It has a compact head with heat source, carbonyl feed and annulus all in one.

21 Baseplate which may be the work piece or a substrate to support the work piece
22 Top view of the head of the nozzle
23 Carbonyl feed
24 Extraction of carbonyl gas to reclamation system
25 Heat source
Side view of compact head to the right of the central drawing

### EXAMPLES OF THE PRESENT INVENTION

### Example 1

The following is a simple example to illustrate the invention.

A flat plate is heated to 140° C., just below the optimum deposition temperature range for carbonyl nickel. The plate can be inexpensive steel, other metal, ceramic, silicon-based polymer or elevated temperature service organic polymer such as PEEK. The plate is enclosed in a pressure vessel and filled with carbon monoxide at a pressure of 1 atmosphere. The nozzle is moved over the substrate by computer control, or manually if desired, and carbonyl nickel gas heated to 175-200° C. accesses, or is impacted onto, the plate. The carbonyl nickel gas decomposes and nickel is deposited directly under the gas stream. The nozzle orifice is opened for wider areal deposition, or closed to build up peak-like features. The reacted carbonyl gas releases carbon monoxide, which is recycled. A 3-D structure is built up that can be machined from the plate in some cases, or the plate surface can be selected such that the nickel does not adhere well and the net shape 3-D object can be easily removed. Examples of such a substrate include ceramics such as borides and oxides, Teflon, graphite, and release agents that contain graphite such as Aquadag.

### Example 2

The above process is performed on a substrate that has features on it that could comprise peaks and valleys, convex and concave geometries, or other desirable features. The substrate is in essence a reusable mold. The mold can be coated with release agents discussed in Example 1. The large cavities can be rapidly built up by a high flow rate in the nozzle, with a wide aperture. External heating can be used as appropriate. Raised detailed features can be deposited under computer or manual control using a thin aperture in the nozzle. The net shape material can be easily extracted from the mold and the process repeated for serial production. This teaching provides excellent detail to the mold and can greatly reduce or eliminate the cost of machining operations to the mold.

### Example 3

A substrate, net shape part will be subjected to corrosion and wear during service. The nozzle can be rastered over the part to apply carbonyl chromium (or other transition element) in a thin layer. The carbonyl gas can then be changed to carbonyl nickel and thereby deposit the nickel over the surface uniformly or selectively in different regions. The next layer can be carbonyl iron or other transition element/alloy. This process can be repeated as desired with a variety of transition elements and/or metal elements doped with elements including boron, carbon and nitrogen. The top layer can be a particularly corrosion resistant or wear resistant layer such as chromium doped with carbon or nickel doped with boron to provide protection over the tough layers below that were formed to improve performance during the anticipated service.

### Example 4

Awaruite (or Josephinite) is a naturally occurring mineral that is largely based on the nickel-iron ordered intermetallic Ni₃Fe. Awaruite is shiny and metallic looking. Awaruite specimens have been found in river beds and carbon dated to 12,000,000 years with no appreciable corrosion! Professor Bird wrote US Pat. Nos. 4,192,765 and 4,433,033, issued in 1984 [9-10], in which he proposes to use Awaruite for corrosion protection on long-term nuclear waste storage containers. To protect steel by the present invention, a base layer of carbonyl nickel could be deposited on the steel part. The present process could be used to deposit carbonyl nickel and carbonyl iron concurrently onto the part and then form the Ni₃Fe intermetallic by annealing the deposited part in the range 550° C. for several hours until the equilibrium Ni₃Fe phase forms. This would provide the surface with an ordered intermetallic known to have corrosion resistance in aqueous environments for many millennia. If the Ni₃Fe ordered intermetallic were to surface check or crack, the ductile nickel underlying layer would continue to provide corrosion resistance. Note that ordered intermetallics are very strong and hard also providing wear resistance. Other intermetallics of transition elements could also be deposited with special resolution as per the present invention.

### Example 5

A precision reflective lens or mirror is desired for a telescope or space application. The machine and process could be used to deposit carbonyl nickel or other highly reflective metal over a substrate that is cast or machined to the approximate desired mirror geometry. Carbonyl gas can be locally deposited to regions to correct for imperfections in the substrate such as making thicker nickel deposits in slight valleys or thinner deposits in slight peaks. Importantly, the substrate temperature can be carefully controlled and the carbonyl gas flow decreased to very slowly build up the top layer to the desired geometry from a CAD/CAM program. The nickel can be deposited with very precise surface that optimizes reflectivity and lens performance in the case of reflective mirrors in Newtonian type telescopes. The process could also be used to coat prisms for use in binoculars.

### Example 6

An electronic device is designed to have a totally corrosion resistant surface with a small localized region of the surface providing ferromagnetic properties and electro-magnetic shielding. Other regions are desired to be non-ferromagnetic. The present invention teaches that carbonyl iron and carbonyl nickel can be applied locally to the surface concurrently at 175° C. in the ratio of approximately 4 parts carbonyl nickel and one part carbonyl iron to form a permalloy composition of about 80wt%Ni-20wt%Fe with ferromagnetic signature and good magnetic shielding. Other regions of the surface can be exposed to silane doped carbonyl nickel at 175° C. to form Ni-4wt%Si or similar alloy which is paramagnetic. Thus, selected regions of the surface can be fabricated with different magnetic properties based on the teachings of the present invention. All regions of the surface have protection from the 80%Ni-20%Fe region or the 96% Ni-4%Si region.

### Example 7

Gun barrel wear is a significant problem for barrels ranging from rotary cannon barrels to conventional machine gun barrels to target barrels. Chromium is well known to extend barrel life but electro-deposition of chromium can involve hexavalent chromium, which is a known carcinogen. Furthermore, electroplated chromium layers can crack from thermal cycling as a barrel heats up and cools. Moreover, chromium electroplating is often not uniform with thicker deposits at sharp edges where electric field strength is higher, and little chromium at radiused regions. Tantalum—10 tungsten (Ta-10 W) has been shown to extend barrel life but its application is problematic and expensive. In the present invention, a mandrel is made that has male rifling features on the surface. The mandrel could be machined from steel, fabricated from thermoplastic or thermoset plastic, or 3-D printed from metal or polymer. The mandrel can be placed in a controlled atmosphere chamber and heated to 240° C. Carbonyl chromium can be applied to the mandrel and hard chromium formed as the carbonyl chromium decomposes. The chromium can be strengthened by minute amounts of carbon in the carbonyl gas introduced from organic compounds. The mandrel could be melted away if made from a thermoplastic resin or pulled out by heating the deposited metal and/or cooling the mandrel through a central cooling channel. The hard chromium liner could be cooled, and inserted into a warm gun barrel tube that is machined to just enable the liner to be inserted when the liner is cool. As the liner equilibrates to room temperature, the liner is shrink—fit into the barrel. Similarly, carbonyl tantalum and carbonyl tungsten can be concurrently impacted to the mandrel and Ta—W alloys deposited. A subsequent anneal could be performed to form tantalum—tungsten alloys, including Ta-10 W when Ta and W are applied in the proper ratios. This liner can be shrink-fit into the barrel as described for chromium.

### Example 8

A metal mold is desired for making complex plastic parts. Finite element modeling that considers carbonyl deposition over a master mold die at about 175-200° C. revealed that a nickel mold of uniform thickness would deform during cooling and removal from the master die. Thickened regions along the highly stressed regions predicted by the model would eliminate such distortion. By the present invention, the master mold die could be made to have depressed channels where the thicker material is desired. The master mold die is placed in a chamber filled with carbon monoxide at near ambient pressure. The nozzle of the present invention is used to deposit nickel locally in the depressed channels whereby the carbonyl gas is heated in the nozzle to above 175° C. The nozzle removes excess carbonyl gas that does not access the surface. After the channels are built, the chamber is filled with carbonyl nickel gas and the nozzle is simultaneously used to supply carbonyl nickel gas over a wider area as the mold is built up. The excess carbonyl gas is reclaimed and recycled. The mold is now strengthened mechanically so that it doesn't deform significantly during cooling or removal from the master mold die.

### Machine, Nozzle Geometry and Deposition System

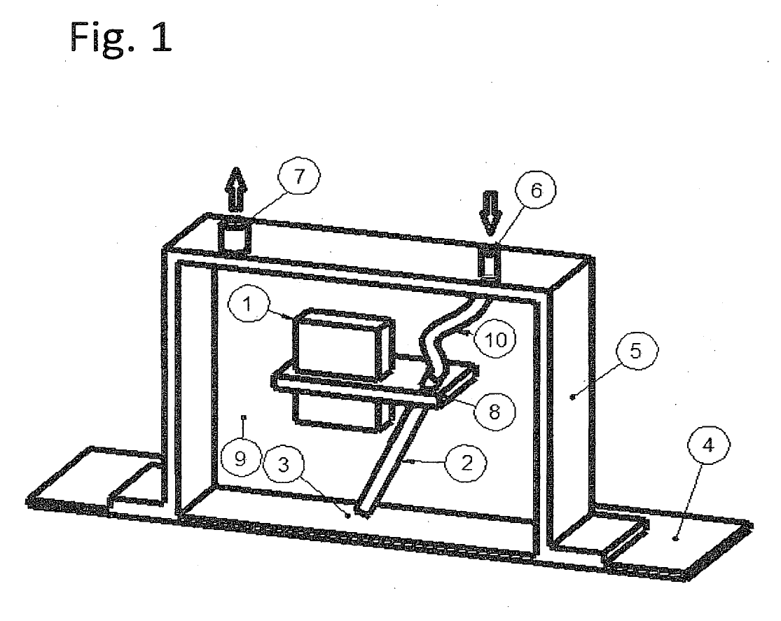

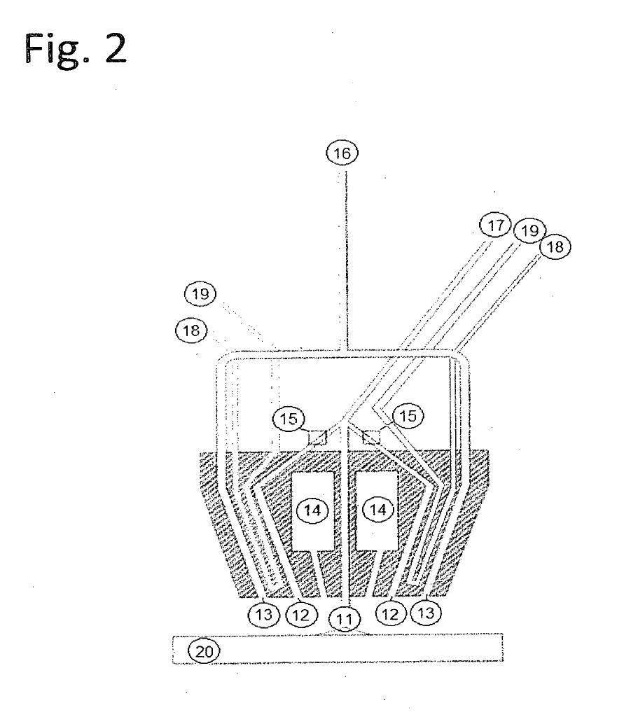

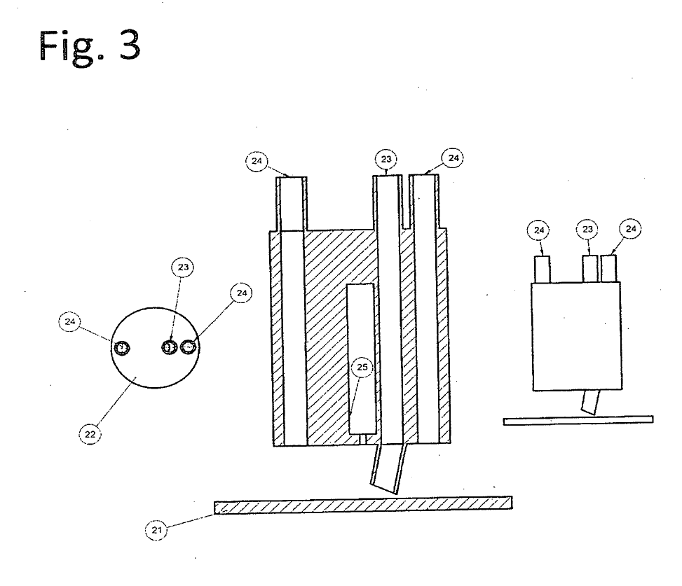

A machine and nozzles for this novel process have been designed as in FIGS. 1 through 3. A controlled atmosphere chamber is heated to 60-70° C. to minimize carbonyl metal deposition on the chamber walls (FIG. 1). Hot carbonyl nickel or other carbonyl gas can pass through a flex hose to a delivery nozzle that is controlled by a 3-D articulated head (FIG. 1). Carbonyl gas is passed through the central orifice to impact the surface to locally build up nickel or other transition metal(s) with fine spacial precision (FIG. 2). Concentric orifices around the central orifice have the capability to pass a large volume of carbonyl gas to a wider area than that covered by the precision, central orifice. The valve could be opened to expose radial orifice's that would feed carbonyl gas or gasses to a wider area when more delocalized build up is desired. In some cases where a significantly raised deposited feature is desired, the radial orifices could be used for shielding the region around the central raised feature by impacting cool carbon monoxide or other shielding gas. As the raised deposited feature is deposited, the reaction product is carbon monoxide. The locale and nearby regions are somewhat cooler by virtue of the endothermic nature of the carbonyl decomposition reaction. The laser or other heat source can deliver heat to the locale where a raised feature is desired to compensate for the heat loss by depositing transition metal atoms by this endothermic decomposition. The cool carbon monoxide or other shielding gas will aid in the fineness of the raised feature by further cooling the adjacent region to a temperature where the transition metal doesn't deposit. In some embodiments of the present invention, the carbonyl gas is heated to above the optimal decomposition range so transition elements do not stick to and clog the nozzle. As the carbonyl gas expands when it leaves the nozzle, it cools to the preferred carbonyl decomposition temperature range.

In general, the nozzle will be cooled to 60-70° C. to prevent carbonyl gases from decomposing prematurely and depositing transition elements on the passages in the nozzle. The gas removal passages 3 in FIG. 2 can be used for cooling. Additional cooling channels as shown (5-6) in FIG. 2 can be added to the nozzle.

For filling a mold with a concave region, the radial orifices and central orifice can be used at high gas flow rates, coupled with laser or other heating to the preferred deposition temperature range, to increase the build-up of transition metal to 150 microns per hour or more. This nozzle has a gas recovery system as shown.

In FIG. 3, an embodiment of a nozzle with greater detail of a gas recovery system is shown. This nozzle design has the advantage of minimizing the amount of carbonyl gas that escapes to the chamber and can deposit where it is undesirable such as away from a desired peak on a substrate, on the heart source, or on the chamber walls. The nozzle can be made of metal, graphite, carbon-carbon composite, or ceramic. If the nozzle is metal such at tool steel, it can be coated with an oxide to minimize carbonyl transition element deposition onto the nozzle.

### REFERENCES

1. A. N. Campbell, A. W. Mullendore, C. R. Hills, J. B. Vandersande , J. Mat Sci, 23, (1988), 4049-58

2. M. Milinkovic, R. P. Reynolds and D. S. Terekhov, “Nickel Vapour Deposition Apparatus and Method”. U.S. Pat. No. 6,132,518, filed Dec. 23, 1999.

3. William C. Jenkin, “Method of Depositing Metal Coatings in holes, tubes, crack, fissures & the like”. U.S. Pat. No. 3,158,499, Nov. 24, 1964,

4. William C. Jenkin, “Method of depositing metals & metallic compounds through-out the pores of porous body”. U.S. Pat. No. 3,160,517, Dec. 8, 1964, Class 117-93.3, Union Carbide

5. William C. Jenkin, “Gas Plated Metal Shell Molds & Patterns”, U.S. Pat. No. 3,167,831, Feb. 2, 1965, Class 22-136, Union Carbide

6. William C. Jenkin, “Deposition Metalizing Bulk Material by Chemical Vapor”, U.S. Pat. No. 4,606,941, Aug. 19, 1986,

7. Juraj Babjak, Victor A. Ettle, and Vladimir Paserin, “Method of Forming Nickel Foam”, US Pat. No. 4,957,543, publication date Sep. 18, 1990.

8. Miroslav Milinkovic, Tony P. Mathews and Kenneth C. Davy, “Mandrel for Use in Nickel Vapor Deposition Processes and Nickel Molds made Therefrom”, U.S. Pat. No. 5,470,651, date of patent, Nov. 28, 1995.

9. John M. Bird, U.S. Pat. No. 4,192,765 issued Mar. 11, 1980. “Container for Radioactive Nuclear Waste Materials”.

10. John M. Bird, U.S. Pat. No. 4,433,033, issued Feb. 21, 1984. “Industrial Metals with Awaruite-Like Synthetic Nickel-Iron Alloys”.

1. A process for depositing transition elements onto a substrate whereby a chemical vapor deposition (CVD) gas or plasma that is temperature controlled, including but not limited to the carbonyl gases, is directed to flow through a nozzle to the substrate upon which the CVD process deposits the transition metal to a predetermined locality on the substrate; where the gas stream can be wide or narrow depending upon the desired area to which the transition metal is applied.

2. A process according to claim 1 where the gas is a carbonyl gas including but not limited to Ni(CO)₄, Fe(CO)₅, Co₂(CO)₈, Cr(CO)₆, W(CO)₆, Mo(CO)₆, Re₂(CO)₁₀ and RuCO₅.

3. A process according to claim 1 where dopants that include but are not limited to B₂H₆, SiH₄, NH₃, CH₄ and other carbo-hydrides are added to the gas stream to add elements such as boron, silicon, nitrogen, and carbon respectively.

4. A process according to claim 1 where the substrate is heated to a temperature in the preferred CVD deposition range.

5. A process according to claim 1 where the substrate is heated to a temperature below the preferred CVD deposition range.

6. A process according to claim 5 where the heat from the CVD gas that passes through the heated nozzle adds sufficient heat to bring the surface of the target substrate to the preferred CVD deposition range in the desired locality.

7. A process according to claim 4 where an external heat source such as a laser heats the desired region for deposition to account for cooling resulting from the endothermic nature of the deposition reaction.

8. A process according to claim 5 where an external heat source such as a laser heats the desired region for deposition to bring it to the optimum deposition temperature range and to account for cooling resulting from the endothermic nature of the deposition reaction.

9. A process according to claim 1 where near net shape parts are made by controlled CVD.

10. A process according to claim 5 where near net shape parts are made by controlled CVD.

11. A process according to claim 1 where different gases are used to deposit different transition elements simultaneously to build up alloys on the substrate.

12. A process according to claim 5 where different gases are used to deposit different transition elements simultaneously to build up alloys on the substrate.

13. A process according to claim 3 where different gases are used to deposit different transition elements simultaneously to build up alloys or metal matrix composites on the substrate.

14. A process according to claim 5 where different gases are used to deposit different transition elements sequentially to build up alloys on the substrate.

15. A process according to claim 1 where different gases are used to deposit different transition elements sequentially to build up laminated transition elements and/or laminated alloys on the substrate.

16. A process according to claim 3 where different gases are used to deposit different transition elements sequentially to build up laminated transition element composites and/or laminated alloys on the substrate.

17. A nozzle that heats a CVD gas or gases in the range 20-500° C. with a variable orifice that directs the gas to a substrate locality.

18. A nozzle that passes cool carbon monoxide or other shielding gas to decrease transition metal build up adjacent to a region where build up is desired

19. A machine that uses a nozzle according to claim 17 that controls atmosphere and pressure.

20. A machine according to claim 8 that applies heat through sources including but not limited to heat lamps, lasers, and electromagnetic devices'.

21. A process and machine according to claim 1 where the deposition location is controlled by a computer or CAD/CAM program.

22. An end use item according to claim 3 that is in part a metal matrix composite or dispersion strengthened alloy.

23. An end use item according to claim 13 that is in part a metal matrix composite.

24. An end use item according to claim 16 that is in part a metal matrix composite.
